(19) United States
(12) Patent Application Publication
(10) Pub. No.: US 2012/0001231 A1
(43) Pub. Date: Jan. 5, 2012

(54) Electrical Fuse

(75) Inventor: Chung Zen Chen, Hsinchu City (TW)

(73) Assignee: ELITE SEMICONDUCTOR MEMORY TECHNOLOGY INC., Hsinchu (TW)

(21) Appl. No.: 12/827,326

(22) Filed: Jun. 30, 2010

(51) Int. Cl. H01L 27/088; H01L 23/525

(52) U.S. Cl. 257/206; 257/209; 257/E27.06; 257/E23.149

(57) ABSTRACT

An electrical fuse comprises first, second, and third thick oxide NMOS transistors and a thin oxide NMOS transistor. The first thick oxide NMOS transistor has a gate connected to a first input signal, and the thin oxide NMOS transistor has a drain connected to the source of the first thick oxide NMOS transistor and a gate shorted to its source. The second thick oxide transistor has a gate connected to a power up signal, a drain connected to the source of the thin oxide NMOS transistor, and a source connected to a reference voltage. The third thick oxide transistor has a gate connected to the second input signal, a drain connected to a high voltage, and a source connected to the drain of the thin oxide NMOS transistor. The first input signal and the second input signal are complementary.

### BACKGROUND OF THE INVENTION

1. Field of the Invention

The present invention relates to an electrical fuse.

2. Description of the Related Art

Semiconductor memory devices are devices in which data can be stored and from which stored data can be retrieved. Semiconductor memory devices can be classified into random access memory (RAM) and read only memory (ROM). RAM is a volatile memory that needs power supply to retain data. ROM is a nonvolatile memory that can retain data even when power is not supplied. Examples of RAM are a dynamic RAM (DRAM) and a static RAM (SRAM). Examples of ROM are a programmable ROM (PROM), an erasable PROM (EPROM), an electrically EPROM (EEPROM), and a flash memory.

As the semiconductor memory technology has developed rapidly, the density of memory cells in current memory devices has increased. This increase in the population of memory cells in the memory device has increased the possibility of defects within one or more memory cells. To ensure that the memory device is fully operational, a redundancy circuit is adapted to replace the defective cell with a redundant memory cell. Upon detecting the defective cell, fuses can be cut or blown open with a laser beam to activate the redundancy circuit.

FIG. 1 shows an example of a fuse and a fuse latch circuit, which are used for a redundancy circuit in a semiconductor memory. The fuse latch unit comprises a pair of cross coupled PMOS transistors P₂ and P₃ and an NMOS transistor N₂. The operation of the fuse R₁ and the fuse latch circuit is explained below. When a supply voltage V_{CC} rises from 0 volts to a predetermined voltage level, a power up signal PU applied to a PMOS transistor P₁ is at a logic low level and thus the fuse latch unit sends a logic low signal from its output node F. When the supply voltage V_{CC} reaches the predetermined voltage level, the power up signal PU switches from logic low level to logic high level, rendering the PMOS transistor P₁ non-conductive. Therefore the voltage at node F is determined according to a conductivity state of the fuse R₁. If the fuse R₁ is melt and changes to an open state, the voltage at node F returns to the previous state. Otherwise, the voltage at node F is at a logic high level since the fuse R₁ is not broken and the transistor N₁ is turned on.

The prior art fuse R₁ needed to be cut by a light source, such as a laser beam. However, such a laser cutting process cannot be performed on a packaged device. Further, the laser cutting method requires a large amount of processing time and a larger chip area so as to ensure the normal operation of adjacent components.

Accordingly, there is a need to provide an electrical fuse that has the ability to repair failed cells in a memory device after it has been placed into a package.

### SUMMARY OF THE INVENTION

An aspect of the present invention is to provide an electrical fuse utilizing MOS oxide breakdown.

According to one embodiment of the present invention, the electrical fuse comprises first, second, third, and fourth thick oxide NMOS transistors and a thin oxide NMOS transistor. The first thick oxide NMOS transistor has a gate connected to a first input signal and the second thick oxide NMOS transistor has a gate connected to a second input signal, a drain connected to the source of the first thick oxide NMOS transistor, and a source connected to a reference voltage. The thin oxide NMOS transistor has a drain connected to the source of the first thick oxide NMOS transistor and a source connected to the reference voltage. The third thick oxide transistor has a gate connected to the second input signal, a drain connected to a high voltage, and a source connected to the gate of the thin oxide NMOS transistor. The fourth thick oxide NMOS transistor has a gate connected to the first input signal, a drain connected to the gate of the thin oxide NMOS transistor, and a source connected to the reference voltage. The first input signal and the second input signal are complementary.

According to another embodiment of the present invention, the electrical fuse comprises first, second, third, fourth, and fifth thick oxide NMOS transistors and a thin oxide NMOS transistor. The first thick oxide NMOS transistor has a gate connected to a first input signal. The second thick oxide NMOS transistor has a gate connected to a second input signal, a drain connected to the source of the first thick oxide NMOS transistor, and a source connected to a reference voltage. The thin oxide NMOS transistor has a drain connected to the source of the first thick oxide NMOS transistor. The third thick oxide transistor has a drain connected to the source of the thin oxide NMOS transistor, a gate connected to the first input signal, and a source connected to the reference voltage. The fourth thick oxide transistor has a gate connected to the second input signal, a drain connected to a high voltage, and a source connected to the gate of the thin oxide NMOS transistor. The fifth thick oxide NMOS transistor has a gate connected to the first input signal, a drain connected to the gate of the thin oxide NMOS transistor, and a source connected to the reference voltage. The first input signal and the second input signal are complementary.

According to yet another embodiment of the present invention, the electrical fuse comprises first, second, and third thick oxide NMOS transistors and a thin oxide NMOS transistor. The first thick oxide NMOS transistor has a gate connected to a first input signal, and the thin oxide NMOS transistor has a drain connected to the source of the first thick oxide NMOS transistor and a gate shorted to its source. The second thick oxide transistor has a gate connected to a power up signal, a drain connected to the source of the thin oxide NMOS transistor N₄, and a source connected to a reference voltage. The third thick oxide transistor has a gate connected to the second input signal, a drain connected to a high voltage, and a source connected to the drain of the thin oxide NMOS transistor. The first input signal and the second input signal are complementary.

### BRIEF DESCRIPTION OF THE DRAWINGS

The invention will be described according to the appended drawings in which:

FIG. 1 shows an example of a fuse and a fuse latch circuit, which are used for a redundancy circuit in a semiconductor memory;

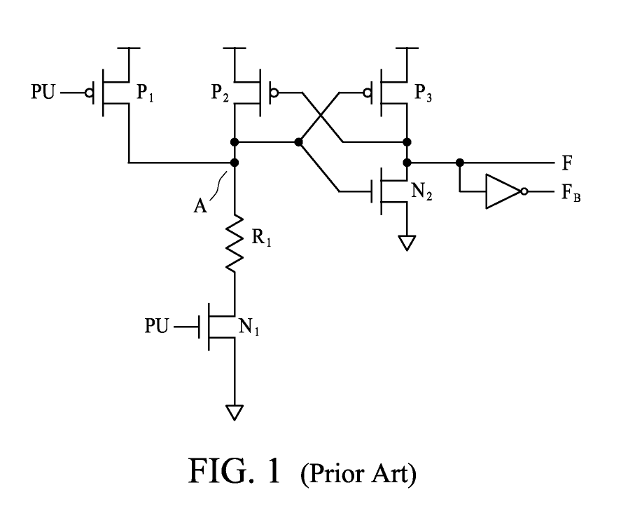

FIG. 2 shows a block diagram of an electrical fuse according to one embodiment of the present invention;

FIG. 3 shows a block diagram of an electrical fuse according to one embodiment of the present invention; and

FIG. 4 shows a block diagram of an electrical fuse according to one embodiment of the present invention.

### DETAILED DESCRIPTION OF THE INVENTION

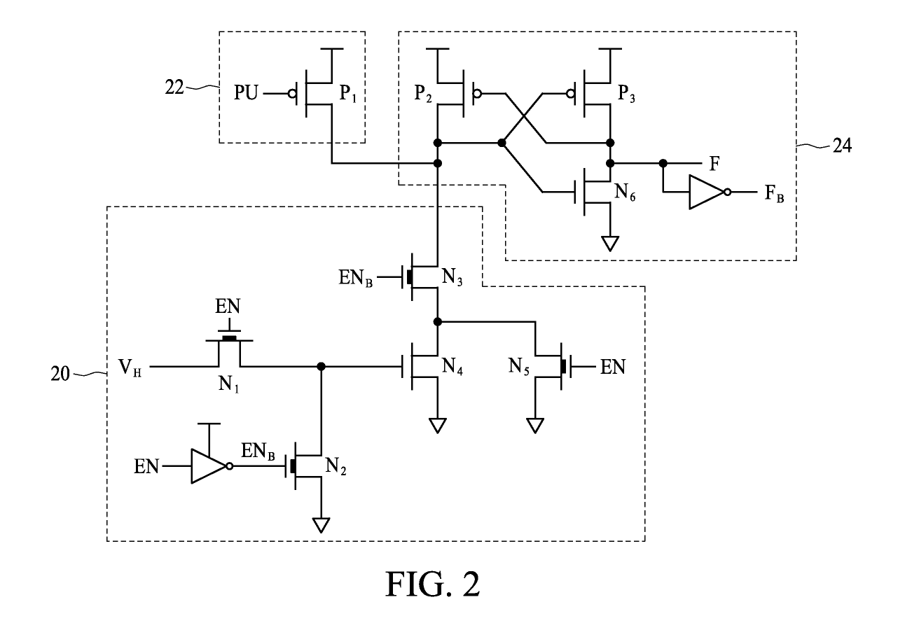

FIG. 2 shows a block diagram of an electrical fuse 20 according to one embodiment of the present invention. The electrical fuse 20 connects to a pull-up device 22 and a latch unit 24 and is configured to receive an enable signal EN and a high voltage V_{H}. The enable signal EN is used to determine the conductivity state of the electrical fuse 20. Referring to FIG. 2, the electrical fuse 20 comprises thick oxide NMOS transistors N₁, N₂, N₃, and N₅ and thin oxide NMOS transistor N₄.

As shown in FIG. 2, the thick oxide NMOS transistor N₃ has a gate connected to the complementary enable signal EN_{B}. The thick oxide NMOS transistor N₅ has a gate connected to the enable signal EN, a drain connected to the source of the thick oxide NMOS transistor N₃, and a source connected to GND. The thin oxide NMOS transistor N₄ has a drain connected to the source of the thick oxide NMOS transistor N₃ and a source connected to GND. The thick oxide transistor N₁ has a gate connected to the enable signal EN, a drain connected to the high voltage V_{H}, and a source connected to the gate of the thin oxide NMOS transistor N₄. The thick oxide NMOS transistor N₂ has a gate connected to complementary enable signal EN_{B}, a drain connected to the gate of the thin oxide NMOS transistor N₄, and a source connected to GND.

The drain of the thick oxide NMOS transistor N₃ is connected to the pull-up device 22 and the latch unit 24. In this embodiment, the pull-up device 22 is a PMOS transistor P₁ having a gate connected to a power up signal PU. In addition, the latch unit 24 comprises a pair of cross coupled PMOS transistors P₂ and P₃ and an NMOS transistor N₆.

The operation of the electrical fuse 20 is explained below. When a supply voltage V_{CC} rises from 0 volts to a predetermined voltage level, the power up signal PU is at a logic low level and the latch unit 24 sends a logic low signal from its output node F. When the supply voltage V_{CC} reaches the predetermined voltage level, the power up signal PU switches from logic low level to logic high level, rendering the PMOS transistor P₁ non-conductive. Therefore the voltage at the node F is determined according to a conductivity state of the NMOS transistor N₄ which is controlled by the enable signal EN. When the enable signal EN is at the logic low level, then the complementary enable signal EN_{B} is at the logic high level, thereby turning on thick oxide NMOS transistors N₂ and N₃ and turning off thick oxide NMOS transistors N₁ and N₅. In this condition, the gate of the thin oxide NMOS transistor N₄ is pulled down to GND, and thus the NMOS transistor N₄ is turned off. Once the NMOS transistor N₄ is turned off, the electrical fuse 20 behaves similar to an open circuit and the voltage at node F returns to the previous state.

When the enable signal EN is at the logic high level, then the complementary enable signal ENB is at the logic low level, thereby turning on thick oxide NMOS transistors N₁ and N₅ and turning off thick oxide NMOS transistors N₂ and N₃. Once the NMOS transistors N₁ and N₅ are turned on, the gate and the drain of the NMOS transistor N₄ are connected to the high voltage V_{H} and GND, respectively. In this condition, a dielectric breakdown occurs between the gate and the drain and between the gate and the source of the NMOS transistor N₄, thereby converting the electrical fuse 20 from an open circuit to a short circuit. In order to protect the latch circuit 24 when the oxide of the NMOS transistor N₄ is broken down, the NMOS transistor N₃ is implemented as a thick oxide transistor.

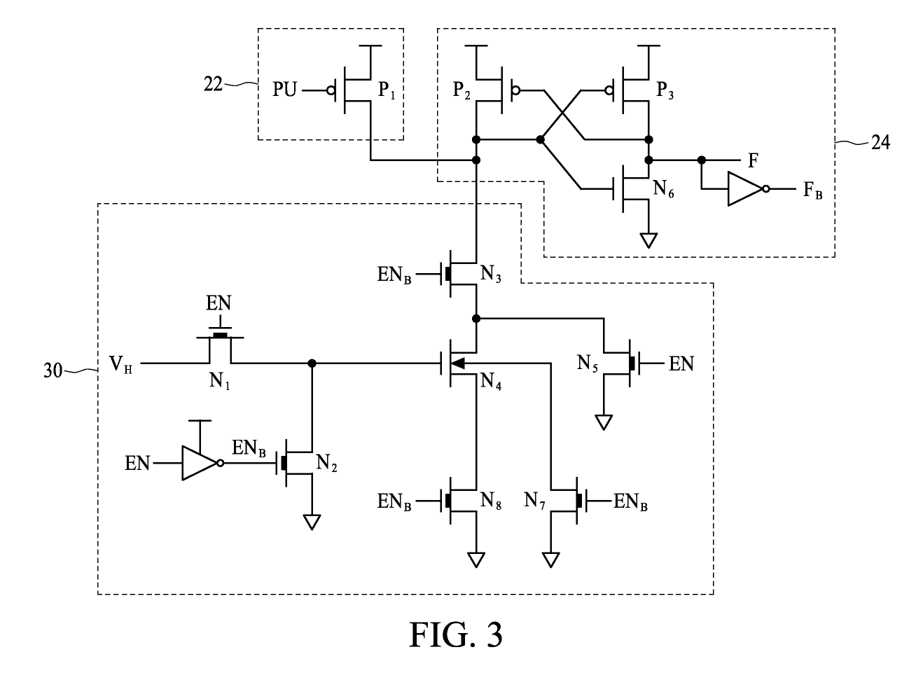

FIG. 3 shows a block diagram of an electrical fuse 30 according to one embodiment of the present invention. The electrical fuse 30 is operated in conjunction with the pull-up device 22 and the latch unit 24. As shown in FIG. 3, the electrical fuse 30 comprises thick oxide NMOS transistors N₁, N₂, N₃, N₅, N₇, and N₈, and thin oxide NMOS transistor N₄.

Referring FIG. 3, the thick oxide NMOS transistor N₃ has a gate connected to the complementary enable signal EN_{B}. The thick oxide NMOS transistor N₅ has a gate connected to the enable signal EN, a drain connected to the source of the thick oxide NMOS transistor N₃, and a source connected to GND. The thick oxide NMOS transistor N₇ has a gate connected to the complementary enable signal EN_{B} and a source connected to GND. The thin oxide NMOS transistor N₄ has a drain connected to the source of the NMOS transistor N₃ and a source connected to the drain of the NMOS transistor N₈. In this embodiment, the bulk of the NMOS transistor N₄ is connected to the drain of the NMOS transistor N₇. However, the bulk of the NMOS transistor N₄ can alternatively be connected to GND. The thick oxide transistor N₈ has a gate connected to the complementary enable signal EN_{B}, a drain connected to the source of the thin oxide NMOS transistor N₄, and a source connected to GND. The thick oxide transistor N₁ has a gate connected to the enable signal EN, a drain connected to the high voltage V_{H}, and a source connected to the gate of the thin oxide NMOS transistor N₄. The thick oxide NMOS transistor N₂ has a gate connected to the complementary enable signal EN_{B}, a drain connected to the gate of the thin oxide NMOS transistor N₄, and a source connected to GND.

The electrical fuse 30 will present either an open circuit or a short circuit depending upon whether the oxide of the thin oxide NMOS transistor N₄ has been broken down. When the enable signal EN is at the logic low level and the complementary enable signal EN_{B} is at the logic high level, the NMOS transistor N₈ turns on, pulling the source of the thin oxide NMOS transistor N₄ down to GND. In this condition, the gate of the NMOS transistor N₄ is connected to GND via transistor N₂, rendering the transistor N₄ non-conductive. Therefore, the electrical fuse 30 operates as an open circuit.

When the enable signal EN is at the logic high level, and the complementary enable signal ENB is at the logic low level, the NMOS transistors N₇ and N₈ turn off, thereby floating the source and the bulk of the NMOS transistor N₄. Since the gate and the drain of the NMOS transistor N₄ are connected to the high voltage V_{H} and GND, respectively, a dielectric breakdown occurs between the gate and the drain of the NMOS transistor N₄. As a result, the gate and the drain of the NMOS transistor N₄ are short-circuited and both connected to GND via NMOS transistor N₂. Therefore, the electrical fuse 30 is converted from an open circuit to a short circuit.

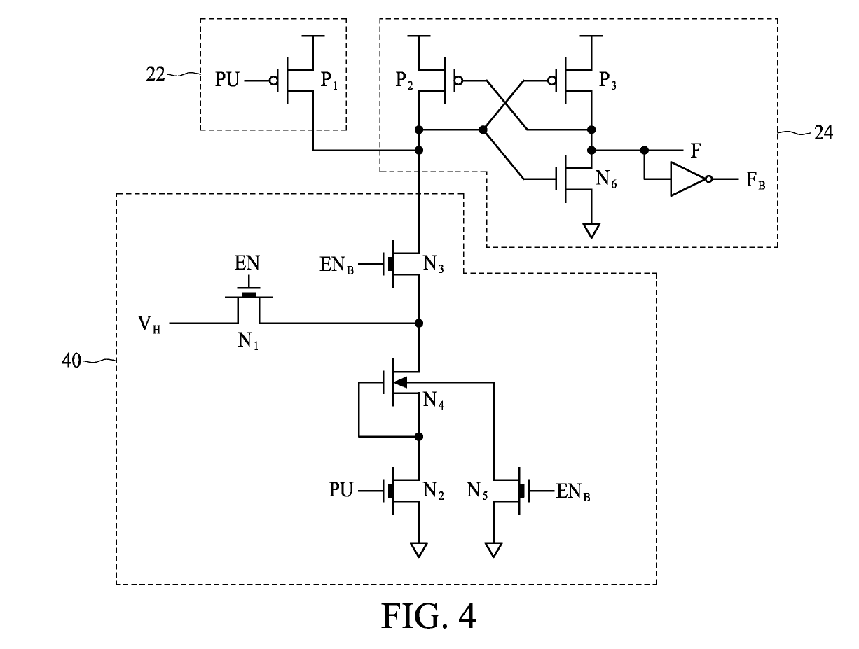

FIG. 4 shows a block diagram of an electrical fuse 40 according to one embodiment of the present invention. The electrical fuse 40 is operated in conjunction with the pull-up device 22 and the latch unit 24. As shown in FIG. 4, the electrical fuse 40 comprises thick oxide NMOS transistors N₁, N₂, N₃, and N₅, and thin oxide NMOS transistor N₄.

Referring FIG. 4, the thick oxide NMOS transistor N₃ has a gate connected to the complementary enable signal EN_{B}. The thin oxide NMOS transistor N₄ has a drain connected to the source of the thick oxide NMOS transistor N₃ and a gate shorted to its source. In this embodiment, the bulk of the NMOS transistor N₄ is connected to the drain of the thick NMOS transistor N₇. However, the bulk of the NMOS transistor N₄ can alternatively be connected to GND. The thick oxide transistor N₂ has a gate connected to the power up signal PU, a drain connected to the source of the thin oxide NMOS transistor N₄, and a source connected to GND. The thick oxide transistor N₁ has a gate connected to the enable signal EN, a drain connected to the high voltage V_{H}, and a source connected to the drain of the thin oxide NMOS transistor N₄. The thick oxide NMOS transistor N₅ has a gate connected to the enable signal EN, a drain connected to the source of the thick oxide NMOS transistor N₃, and a source connected to GND.

The electrical fuse 40 will present either an open circuit or a short circuit depending upon whether the oxide of the thin oxide NMOS transistor N₄ has been broken down. When the power up signal PU is at the logic high level, the NMOS transistor N₂ turns on, pulling the source of the thin oxide NMOS transistor N₄ down to GND. Since the voltage between the gate and the source of the NMOS transistor N₄ is zero, the transistor N₄ is non-conductive when the enable signal EN is at the logic low level. Therefore, the electrical fuse 20 operates as an open circuit.

When the enable signal EN is at the logic high level, and the complementary enable signal ENB is at the logic low level, the drain of the NMOS transistor N₄ is connected to the high voltage V_{H}. In this condition, a dielectric breakdown occurs between the gate and the drain of the NMOS transistor N₄. Since the source of the NMOS transistor N₄ is connected to GND via the NMOS transistor N₂, the drain of the NMOS transistor N₄ is shorted to GND. As a result, the electrical fuse 40 is converted from an open circuit to a short circuit.

The thick oxide NMOS transistor N₃ is connected to the pull-up device 22 and the latch unit 24 so as to protect the circuits when the oxide of the NMOS transistor N₄ is broken down. The bulk of the NMOS transistor N₄ can be connected to GND or floated depending on the junction breakdown voltage. If the junction breakdown voltage is higher than the high voltage V_{H}, the bulk of the NMOS transistor N₄ can be connected to GND directly.

The above-described embodiments of the present invention are intended to be illustrative only. Numerous alternative embodiments may be devised by those skilled in the art without departing from the scope of the following claims.

What is claimed is:

1. An electrical fuse, comprising:
a first thick oxide n-channel MOSFET (NMOS) transistor having a gate connected to a first input signal;
a second thick oxide NMOS transistor having a gate connected to a second input signal, a drain connected to a source of the first thick oxide NMOS transistor, and a source connected to a reference voltage;
a thin oxide NMOS transistor having a drain connected to the source of the first thick oxide NMOS transistor and a source connected to the reference voltage;
a third thick oxide transistor having a gate connected to the second input signal, a drain connected to a high voltage, and a source connected to a gate of the thin oxide NMOS transistor; and
a fourth thick oxide NMOS transistor having a gate connected to the first input signal, a drain connected to the gate of the thin oxide NMOS transistor, and a source connected to the reference voltage;
wherein the first input signal and the second input signal are complementary.

2. The electrical fuse of claim 1, further comprising a pull-up device and a latch unit both connected to the drain of the first thick oxide NMOS transistor.

3. An electrical fuse, comprising:
a first thick oxide NMOS transistor having a gate connected to a first input signal;
a second thick oxide NMOS transistor having a gate connected to a second input signal, a drain connected to a source of the first thick oxide NMOS transistor, and a source connected to a reference voltage;
a thin oxide NMOS transistor having a drain connected to the source of the first thick oxide NMOS transistor;
a third thick oxide transistor having a drain connected to a source of the thin oxide NMOS transistor, a gate connected to the first input signal, and a source connected to the reference voltage;
a fourth thick oxide transistor having a gate connected to the second input signal, a drain connected to a high voltage, and a source connected to a gate of the thin oxide NMOS transistor; and
a fifth thick oxide NMOS transistor having a gate connected to the first input signal, a drain connected to the gate of the thin oxide NMOS transistor, and a source connected to the reference voltage;
wherein the first input signal and the second input signal are complementary.

4. The electrical fuse of claim 3, further comprising a pull-up device and a latch unit both connected to the drain of the first thick oxide NMOS transistor.

5. The electrical fuse of claim 3, wherein a bulk of the thin oxide NMOS transistor is connected to the reference voltage.

6. The electrical fuse of claim 3, further comprising a sixth thick oxide NMOS transistor having a gate connected to the first input signal, a drain connected to a bulk of the thin oxide NMOS transistor, and a source connected to the reference voltage.

7. An electrical fuse, comprising:
a first thick oxide NMOS transistor having a gate connected to a first input signal;
a thin oxide NMOS transistor having a drain connected to a source of the first thick oxide NMOS transistor and a gate connected to a source of the thin oxide NMOS;
a second thick oxide transistor having a gate connected to a power up signal, a drain connected to the source of the thin oxide NMOS transistor, and a source connected to a reference voltage;
a third thick oxide transistor having a gate connected to the second input signal, a drain connected to a high voltage, and a source connected to the drain of the thin oxide NMOS transistor; and
wherein the first input signal and the second input signal are complementary.

8. The electrical fuse of claim 7, further comprising a pull-up device and a latch unit both connected to the drain of the first thick oxide NMOS transistor.

9. The electrical fuse of claim 7, wherein a bulk of the thin oxide NMOS transistor is connected to the reference voltage.

10. The electrical fuse of claim 7, further comprising a fourth thick oxide NMOS transistor having a gate connected to the first input signal, a drain connected to a bulk of the thin oxide NMOS transistor, and a source connected to the reference voltage.
